(19) United States
(12) Patent Application Publication
(10) Pub. No.: US 2020/0216307 A1
(43) Pub. Date: Jul. 9, 2020

(54) METHOD FOR MANUFACTURING DUAL-CAVITY STRUCTURE, AND DUAL-CAVITY STRUCTURE

(71) Applicant: CSMC TECHNOLOGIES FAB2 CO., LTD., Jiangsu (CN)

(72) Inventors: Dan Dai, Jiangsu (CN); Changfeng Xia, Jiangsu (CN); Juanjuan Dong, Jiangsu (CN)

(21) Appl. No.: 16/628,001

(22) PCT Filed: Jul. 3, 2018
(86) PCT No.: PCT/CN2018/094252

§ 371 Date: Dec. 31, 2019

(30) Foreign Application Priority Data
Jul. 3, 2017 (CN) 201710534699.3

(51) Int. Cl. B81C 1/00; B81B 1/00

(52) U.S. Cl. CPC B81C 1/00047; B81B 1/002; B81B 2201/0264; B60C 23/02; B81C 2201/0125; B81C 2201/0132; B81C 2201/0177; B81B 2203/0315

(57) ABSTRACT

A method for manufacturing a dual-cavity structure and a dual-cavity structure, including: etching on a semiconductor substrate to form a first trench array, tops of the first trench array being separated from each other and bottoms thereof being communicated with each other to form a first cavity; growing a first epitaxial layer on the semiconductor substrate on which the first trench array is formed, to cover the first trench array by the first epitaxial layer; etching on the first epitaxial layer to form a second trench array; tops of the second trench array being separated from each other and bottoms thereof being communicated with each other to form a second cavity; growing a second epitaxial layer on the first epitaxial layer on which the second trench array is formed; and etching the first epitaxial layer and the second epitaxial layer to form a straight groove.

### TECHNICAL FIELD

The present disclosure relates to the field of semiconductor technologies, more particularly, to a method for manufacturing a dual-cavity structure and a dual-cavity structure.

### BACKGROUND

A semiconductor device includes various electronic devices that use special electrical properties of semiconductor materials to implement specific functions. For specific functions of different devices, some devices require for manufacturing trench structures or cavity structures in various shapes in a semiconductor substrate to meet design requirements. Especially in Micro Electro Mechanical Systems (MEMS), it is needed to manufacture trenches and cavities with complex structures on the substrate to form the desired micro-mechanisms and devices. Generally, the cavity-epitaxial structure manufactured by an epitaxial method may result in a recess problem caused by the cavity depression when the epitaxial layer is too thick. The recesses may cause defects in the subsequent photolithography process or the like due to the flatness, and the subsequent processes cannot be further performed.

### SUMMARY

In view of above, it is necessary to provide a method for manufacturing a dual-cavity structure and a dual-cavity structure.

Provided is a method for manufacturing a dual-cavity structure, including:

etching on a semiconductor substrate to form a first trench array; wherein tops of the first trench array are separated from each other, and bottoms thereof are communicated with each other to form a first cavity;

growing a first epitaxial layer on the semiconductor substrate on which the first trench array is formed, to cover the first trench array by the first epitaxial layer;

etching on the first epitaxial layer to form a second trench array, wherein tops of the second trench array are separated from each other, and bottoms thereof are communicated with each other to form a second cavity;

growing a second epitaxial layer on the first epitaxial layer on which the second trench array is formed; and

etching the first epitaxial layer and the second epitaxial layer to form a straight groove communicated with the first cavity.

Details of one or more embodiments of the present disclosure are set forth in the accompanying drawings and description below. Other features, objects, and advantages of the disclosure will be apparent from the description, the accompanying drawings and the appended claims.

On the other hand, further provided is a dual-cavity structure, including:

a semiconductor substrate;

a first trench array, arranged on the semiconductor substrate, wherein tops of the first trench array are separated from each other, and bottoms of the trenches are communicated with each other to form a first cavity;

a first epitaxial layer, arranged on the semiconductor substrate, covering the first trench array;

a second trench array, arranged on the first epitaxial layer, wherein tops of the second trench array are separated from each other, and bottoms thereof are communicated with each other to form a second cavity;

a second epitaxial layer, arranged on the first epitaxial layer, covering the second trench array;

a straight groove, arranged on the first epitaxial layer and the second epitaxial layer to communicate with the first cavity.

### BRIEF DESCRIPTION OF THE DRAWINGS

For the purpose of illustrating the technical solutions of the embodiments of the present disclosure or of the prior art more explicitly, the accompanying drawings to be used necessarily for the description of the embodiments or the prior art will be briefly described below. Apparently, the accompanying drawings described below are part of the embodiments of the disclosure only, accompanying drawings of the other embodiments may further be acquired based on these accompanying drawings herein without creative efforts to those of ordinary skill in the art.

FIG. 1 is a flow diagram of the method for manufacturing the dual-cavity structure according to an embodiment.

FIGS. 2A-2F is a cross-sectional view of the dual-cavity structure obtained after each steps of the method for manufacturing the dual-cavity structure according to an embodiment are completed.

FIG. 3 is a structural appearance view of a first epitaxial layer in one embodiment.

FIG. 4 is a structure appearance view of the conventional epitaxial layer.

FIG. 5 is a partial flow diagram of the method for manufacturing the dual-cavity structure according to another embodiment.

FIG. 6 is a partial flow diagram of the method for manufacturing the dual-cavity structure according to yet another embodiment.

### DETAILED DESCRIPTION OF THE EMBODIMENTS

In order to make the objects, technical solutions and advantages of the present disclosure more comprehensible, the present disclosure will be described in detail below with reference to the accompanying drawings and embodiments. It should be understood that the detailed embodiments described herein is merely to set forth the present disclosure, but not intended to limit the present disclosure.

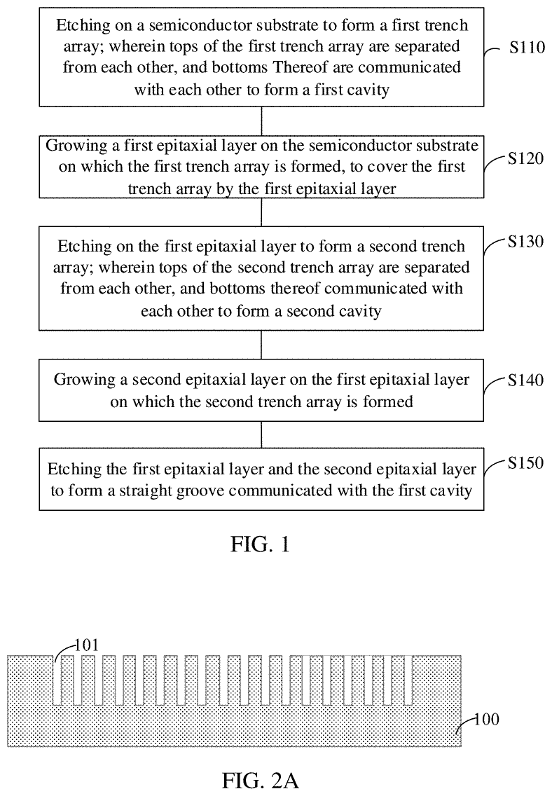

As shown in FIG. 1, a flow diagram of the method for manufacturing a dual-cavity structure is shown. In an embodiment, the method for manufacturing the dual-cavity structure includes the following steps.

In a step S110, the semiconductor substrate is etched to form a first trench array. Tops of the first trench array are separated from each other and bottoms thereof are communicated with each other to form a first cavity.

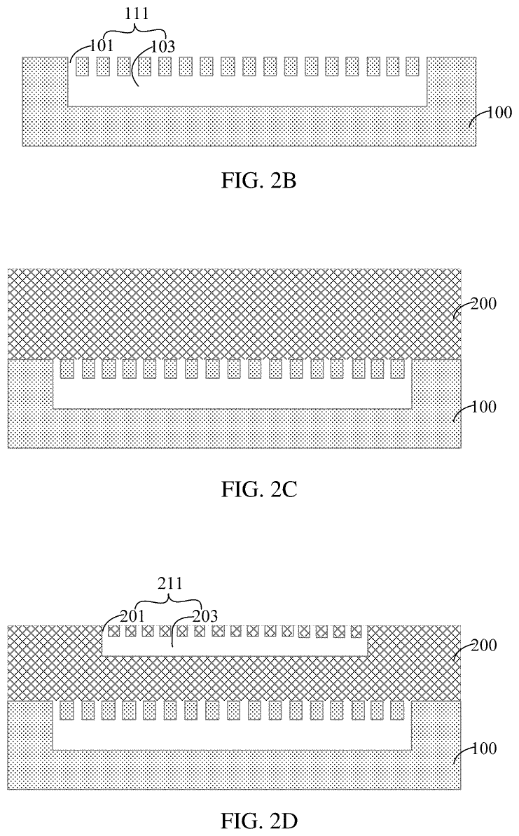

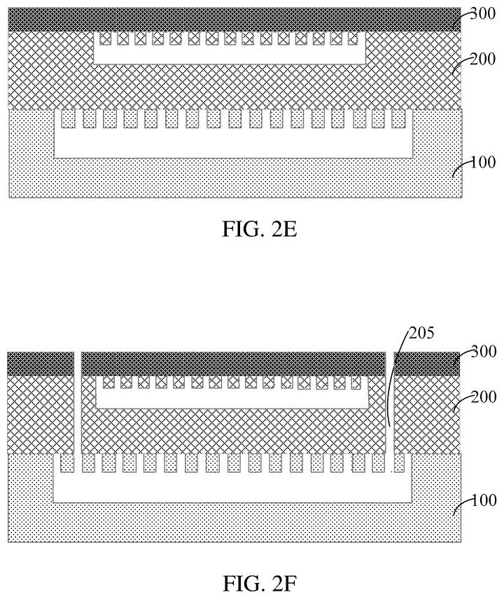

As shown in FIG. 2A and FIG. 2B, the constituent material of the semiconductor substrate 100 may be undoped monocrystalline silicon, monocrystalline silicon doped with impurities, silicon on insulator (SOI), stacked silicon on insulator (SSOI), stacked silicon germanium on insulator (S—SiGeOI), and silicon germanium on insulator (SiGeOI), or the like. As an example, in the embodiment, monocrystalline silicon is selected as the constituent material of the semiconductor substrate 100.

The semiconductor substrate 100 is etched to form the first trench array 111. The first trench array 111 includes a plurality of trenches 101. The tops of the plurality of trenches 101 are separated from each other and the bottoms of the plurality of trenches 101 are communicated with each other to form the first cavity 103. Specifically, etching the semiconductor substrate 100 to form the first trench array 111, specifically includes: etching the semiconductor substrate 100 anisotropically to form the plurality of trenches 101 separated from each other, referring to FIG. 2A; etching the bottoms of the plurality of trenches 101 isotropically to result in communication of the bottoms of the plurality of trenches 101 to form the first cavity 103, referring to FIG. 2B.

When the semiconductor is anisotropically etched, plasma etching is used, so that it is easy to form a plurality of trenches 101 having a small aperture, good verticality, and relatively large depth and width. The number, shape (for example, circular or square) and the specific arrangement of the plurality of trenches 101 are not limited, and may be selected by those skilled in the art according to the shape and size of the region for forming the cavity, the etching conditions and the like.

The bottoms of the plurality of trenches 101 are etched isotropically by plasma dry etching. During the etching process, the process conditions for the reactive ion etching are controlled so that the bottoms of the plurality of trenches 101 are communicated to form the first cavity 103, by using SF6, CF4 or other gases, which are characterized by a higher etching rate in the direction along the arrangement of the array of trenches 101 than that in the extending direction of the trenches 101, and are etched laterally at a faster rate until the silicon substrate between the bottoms of the trenches 101 is etched away. The specific shape and the size of the first cavity 103 are also not limited either.

In a step S120, a first epitaxial layer is grown on the semiconductor substrate on which the first trench array is formed to cover the first trench array.

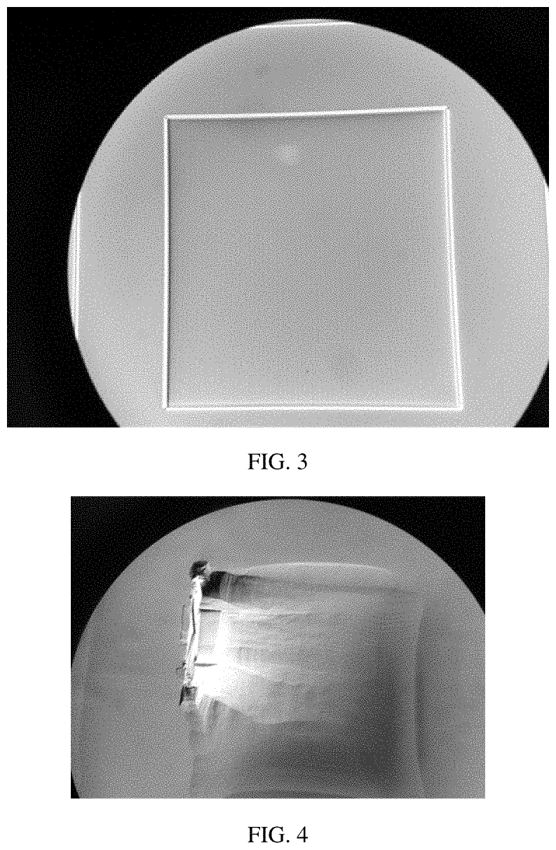

As shown in FIG. 2C, in an embodiment, the first epitaxial layer 200 is formed by low-pressure growth in a single wafer epitaxial furnace, and the process reference range may be set to a pressure range of 30 Torr to 80 Torr, wherein 1 Torr=133.322 Pa; a temperature range of 1100° C. to 1200° C., and a growth rate about 1 to 2 μm/min. The thickness of the first epitaxial layer 200 is in a range from 30 μm to 60 μm. In the embodiment, the thickness of the first epitaxial layer 200 is 30 μm. By controlling the epitaxial growth rate and the epitaxial growth time, the thickness of the epitaxial layer may be precisely controlled. The surface of the first epitaxial layer 200 generated by this method has almost no defects, and the surface of the first epitaxial layer 200 is relatively flat as shown in FIG. 3., having a maximum depression depth of steps of 0.88 μm. However, since by using an atmospheric pressure epitaxial process (chemical solution deposition technology) or the like, the conventional multi-wafer epitaxial equipment grows a thick epitaxial layer of 30-60 μm, it is easier to generate defects on the surface of the structure, while steps with irregular depressions of 3-5 μm are formed as shown in FIG. 4, resulting in a very uneven surface. By forming the first epitaxial layer 200 by the low-pressure growth using a single wafer epitaxial furnace, the problem that the steps are too large and uneven due to the excessive thickness of the first epitaxial layer 200 may be avoided.

In a step S130, the first epitaxial layer is etched to form a second trench array. The tops of the first trench array are separated from each other and the bottoms are communicated with each other to form a second cavity.

As shown in FIG. 2D, the first epitaxial layer 200 is etched to form the second trench array 211. The second trench array 211 includes a plurality of trenches 201. The tops of the plurality of trenches 201 are separated from each other, and the bottoms of the plurality of trenches 201 are communicated with each other to form the second cavity 203. The step specifically includes: etching on the first epitaxial layer 200 anisotropically to form the plurality of trenches 201 separated from each other; etching the bottoms of the plurality of trenches 201 isotropically so that the bottoms of the plurality of trenches 201 are communicated with each other to form the second cavity 203.

When the first epitaxial layer 200 is anisotropically etched, plasma etching is used, so that it is easy to form the plurality of trenches 201 having a small aperture, good verticality, and relatively large depth and width. The number, shape (for example, circular or square) and the specific arrangement of the plurality of trenches 201 are not limited, and may be selected by those skilled in the art according to the shape and size of the region for forming the cavity, the etching conditions and the like.

The bottoms of the plurality of trenches 201 are etched isotropically by plasma dry etching. During the etching process, the process conditions for the reactive ion etching are controlled so that the bottoms of the plurality of trenches 201 are communicated to form the second cavity 203, by using SF6, CF4 or other gases, which are characterized by a higher etching rate in the direction along the arrangement of the array of trenches 201 than that in the extending direction of the trenches 201, and are etched laterally at a faster rate until the silicon substrate between the bottoms of the trenches 201 is etched away. The specific shape and the size of the second cavity 203 are also not limited either.

In an embodiment, the depth range of the formed second trench array 211 is about 12 μm. Since the thickness of the first epitaxial layer 200 is in a range between 30 μm to 60 μm, the etching space is large enough to form the second trench array 211 without destroying the first trench array 111 during the process of forming the second trench array 211.

In an embodiment, the distance between the tops of the trenches in the first trench array 111 and the bottoms of the trenches in the second trench array 211 is greater than or equal to 15 μm. That is, a safe distance between the first trench array 111 and the second trench array 211 is retained so that they will not affect each other during etching.

In a step S140, a second epitaxial layer is grown on the first epitaxial layer on which the second trench array is formed.

As shown in FIG. 2E, in an embodiment, the second epitaxial layer 200 is formed by low-pressure growth in a single wafer epitaxial furnace, and the process reference range may be set to: a pressure range of 30 Torr to 80 Torr, wherein 1 Torr=133.322 Pa; a temperature range of 1100° C. to 1200° C., and a growth rate about 1 to 2 μm/min. The thickness range of the second epitaxial layer 300 is less than 20 μm. In the embodiment, the thickness of the second epitaxial layer 300 is 15 μm. By controlling the epitaxial growth rate and the epitaxial growth time, the thickness of the epitaxial layer may be precisely controlled.

In a step S150, the first epitaxial layer and the second epitaxial layer are etched to form a straight groove communicated with the first cavity.

As show in FIG. 2F, by plasma dry anisotropical etching, the first epitaxial layer 200 and the second epitaxial layer 300 are etched to form the straight groove 205 communicated with the first cavity 103. The number and shape (for example, circular or square) and the specific arrangement of the straight groove 205 are not specifically defined.

In an embodiment, prior to the step of forming the straight groove 205 communicated with the first cavity 103, process steps such as photolithography, ion implantation, high-speed drying of the wet process or the like may also be performed according to the type of the formed semiconductor device. That is, after the second epitaxial layer 300 is formed and before the straight groove 205 is formed, a defect-free photolithography etching process with a small line width may be performed. Moreover, since the dual-cavity structure is stable, after the high-speed drying of the wet process, the phenomenon of breakage or shedding will not occur on the surface of the first epitaxial layer 200 or the second epitaxial layer 300.

The surface of the first epitaxial layer 200 of the dual-cavity structure formed by the above method is flat and has almost no defects, and after the second epitaxial layer 300 is formed, the defect-free photolithography etching process with the small line width may be further performed. Moreover, since the dual-cavity structure is stable, after the high-speed drying of the wet process, the phenomenon of breakage or shedding will not occur on the surface of the first epitaxial layer 200 or the second epitaxial layer 300. Meanwhile, a Tire Pressure Monitoring System (TPMS), a mass block or the like may be formed on the surface of the second epitaxial layer 300 of the formed dual-cavity structure by providing the straight groove 205 communicated with the first cavity 103.

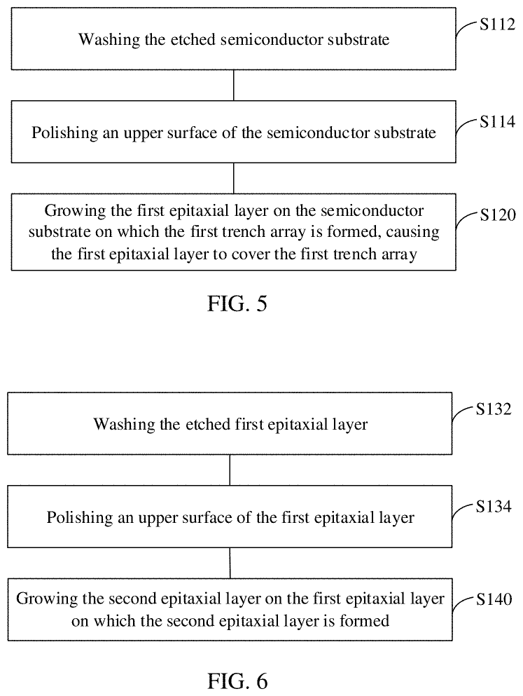

As shown in FIG. 5, in an embodiment, prior to growing the first epitaxial layer on the semiconductor substrate on which the first trench array is formed, the method further includes the following steps.

In a step S112, the etched semiconductor substrate is washed.

The object of washing the etched semiconductor substrate 100 is to remove the contaminant impurities on the surface of the semiconductor substrate 100. In this embodiment, the semiconductor substrate 100 is washed with an acidic liquid.

In a step 114, the upper surface of the semiconductor substrate is polished.

The upper surface of the washed semiconductor substrate 100 is polished, that is, the surface of the semiconductor substrate 100 for forming the first epitaxial layer 200 is polished. The impurity particles on the surface of the semiconductor substrate 100 may be removed by the polishing process to obtain a flat surface of the semiconductor substrate 100.

As shown in FIG. 6, in an embodiment, prior to the step of growing the second epitaxial layer on the first epitaxial layer on which the second trench array is formed, the method further includes the following steps.

In a step S132, the etched first epitaxial layer is washed.

The object of washing the etched first epitaxial layer 200 is to remove the contaminant impurities on the surface of the first epitaxial layer 200. In this embodiment, the first epitaxial layer 200 is washed with an acidic liquid.

In a step 134, the upper surface of the first epitaxial layer is polished.

The upper surface of the washed first epitaxial layer 200 is polished, that is, the surface of the first epitaxial layer 200 for forming the second epitaxial layer 300 is polished. The impurity particles on the surface of the first epitaxial layer 200 may be removed by the polishing process to obtain a flat surface of the first epitaxial layer 200.

All of the technical features in the embodiments can be employed in arbitrary combinations. For purpose of simplifying the description, not all arbitrary combinations of the technical features in the embodiments illustrated above are described. However, as long as such combinations of the technical features are not contradictory, they should be considered as within the scope of the disclosure in the specification.

The above embodiments are merely illustrative of several implementations of the disclosure, and the description thereof is more specific and detailed, but should not be deemed as limitations to the scope of the present disclosure. It should be noted that variations and improvements will become apparent to those skilled in the art to which the present disclosure pertains without departing from its scope. Therefore, the scope of the present disclosure is defined by the appended claims.

What is claimed is:

1. A method for manufacturing a dual-cavity structure, comprising:
etching on a semiconductor substrate to form a first trench array; wherein tops of the first trench array are separated from each other, and bottoms thereof are communicated with each other to form a first cavity;
growing a first epitaxial layer on the semiconductor substrate on which the first trench array is formed, to cover the first trench array by the first epitaxial layer;
etching on the first epitaxial layer to form a second trench array; wherein tops of the second trench array are separated from each other, and bottoms thereof are communicated with each other to form a second cavity;
growing a second epitaxial layer on the first epitaxial layer on which the second trench array is formed; and
etching the first epitaxial layer and the second epitaxial layer to form a straight groove communicated with the first cavity.

2. The method of claim 1, wherein prior to the step of growing the first epitaxial layer on the semiconductor substrate on which the first trench array is formed, the method further comprises:
washing the etched semiconductor substrate; and
polishing an upper surface of the semiconductor substrate.

3. The method of claim 1, wherein the step of etching on the semiconductor substrate to form the first trench array comprises:
etching the semiconductor substrate anisotropically to form a plurality of trenches separated from each other; and
etching bottoms of the plurality of trenches isotropically so that the bottoms of the plurality of trenches are communicated with each other to form the first cavity.

4. The method of claim 1, wherein prior to the step of growing the second epitaxial layer on the first epitaxial layer on which the second trench array is formed, the method further comprises:
washing the etched first epitaxial layer; and
polishing an upper surface of the first epitaxial layer.

5. The method of claim 1, wherein the step of etching the first epitaxial layer and the second epitaxial layer to form the straight groove communicated with the first cavity comprises:
etching the first epitaxial layer and the second epitaxial layer anisotropically to form the straight groove communicated with the first cavity.

6. The method of claim 1, wherein a thickness of the first epitaxial layer is in a range from 30 μm to 60 μm.

7. The method of claim 1, wherein a thickness of the second epitaxial layer is less than 20 μm.

8. The method of claim 1, wherein a distance between the tops of the first trench array and the bottoms of the second trench array is greater than or equal to 15 μm.

9. The method of claim 1, wherein the first epitaxial layer and the second epitaxial layer are formed by low-pressure growth in a single wafer epitaxial furnace.

10. The method of claim 9, wherein process parameters range of the low-pressure growth comprises: a pressure range of 30 Torr to 80 Torr; and a temperature range of 1100° C. to 1200° C.

11. A dual-cavity structure, comprising:
a semiconductor substrate;
a first trench array arranged on the semiconductor substrate, wherein tops of the first trench array are separated from each other, and bottoms thereof are communicated with each other to form a first cavity;
a first epitaxial layer arranged on the semiconductor substrate, to cover the first trench array;
a second trench array arranged on the first epitaxial layer, wherein tops of the second trench array are separated from each other, and bottoms thereof are communicated with each other to form a second cavity;
a second epitaxial layer arranged on the first epitaxial layer, to cover the second trench array; and
a straight groove arranged on the first epitaxial layer and the second epitaxial layer to communicate with the first cavity.

12. The dual-cavity structure of claim 11, wherein a thickness of the first epitaxial layer is in a range from 30 μm to 60 μm.

13. The dual-cavity structure of claim 11, wherein a thickness of the second epitaxial layer is less than 20 μm.

14. The dual-cavity structure of claim 11, wherein a distance between the tops of the first trench array and the bottoms of the second trench array is greater than or equal to 15 μm.

15. The dual-cavity structure of claim 11, wherein the first epitaxial layer and the second epitaxial layer are formed by low-pressure growth in a single wafer epitaxial furnace.

16. The method of claim 15, wherein process parameters range of the low-pressure growth comprises: a pressure range of 30 Torr to 80 Torr; a temperature range of 1100° C. to 1200° C.
